(19) United States
(12) Patent Application Publication
(10) Pub. No.: US 2023/0040780 A1
(43) Pub. Date: Feb. 9, 2023

(54) CLASS INVERSE F DOHERTY AMPLIFIER

(71) Applicant: SKYWORKS SOLUTIONS, INC., Irvine, CA (US)

(72) Inventor: Mingming Liu, Cedar Rapids, IA (US)

(21) Appl. No.: 17/809,937

(22) Filed: Jun. 30, 2022

Related U.S. Application Data
(60) Provisional application No. 63/234,746, filed on Aug. 19, 2021.
(60) Provisional application No. 63/226,849, filed on Jul. 29, 2021.

(51) Int. Cl. H03F 1/02; H03F 3/21

(52) U.S. Cl. CPC H03F 1/0288; H03F 3/211; H03F 2200/451

(57) ABSTRACT

A Doherty power amplifier comprising: an input configured to receive an input signal to be amplified and to split the input signal into a first portion and a second portion, the input signal having an operating frequency; a carrier amplifier path coupled to the input to receive the first portion, the carrier amplifier path including a carrier amplifier coupled to a differential inverter, the carrier amplifier being configured to amplify the first portion and provide an amplified first portion to the differential inverter, the differential inverter having a capacitance configured to make the differential inverter behave as a short circuit at odd harmonics of the operating frequency, the capacitance coupling a first path and a second path of the differential inverter in parallel; and a peaking amplifier path coupled to the input to receive the second portion and comprising a peaking amplifier configured to amplify the second portion.

### CROSS-REFERENCE TO RELATED APPLICATIONS

This application claims priority under 35 U.S.C. § 119(e) to U.S. Provisional Application Ser. No. 63/226,849, titled “CLASS INVERSE F DOHERTY AMPLIFIER,” filed on 29 Jul. 2021, and to U.S. Provisional Application Ser. No. 63/234,746, titled “CLASS INVERSE F DOHERTY AMPLIFIER,” filed on 19 Aug. 2021, each of which is hereby incorporated by reference in its entirety.

### BACKGROUND

### Field

Examples of the disclosure relate to a Doherty power amplifier, a method for amplifying a radio-frequency (RF) signal, and a power amplifier module.

### Description of the Related Technology

Power amplifiers may be used in RF communication systems to amplify RF signals for transmission via antennas. It may be desirable to manage the power of RF signal transmissions to prolong battery life and/or to provide a suitable transmit power level.

The Doherty amplifier is a linear power amplifier that may operate at low power consumption levels and high efficiencies. The Doherty amplifier may include a main or carrier amplifier and a peak amplifier. At low power level, only the carrier amplifier may be active. At higher power levels, the peak amplifier starts to work which increases the voltage swing across the load impedance. The peaking amplifier enters operation just before the carrier amplifier starts to run into compression.

Although the Doherty amplifier has advantages in certain applications, the Doherty amplifier may encounter disadvantages when implemented, for example, in low-cost radio-frequency (RF) integrated circuits (ICs) for use in wireless communications equipment. In some examples, Doherty amplifiers may be designed at low enough frequencies and/or high enough impedances that parasitic s such as bond-wire inductance and stray capacitance are not a significant factor. As such, portions of the amplifier system may be implemented off-chip, that is, outside the RF IC containing the Doherty amplifier.

Different classes of amplifier have been applied to Doherty amplifiers, such as broadband amplifiers. For example, classes of amplifier such as B and E may be used. However, such amplifiers may experience large voltage swing, AMPM soft compression, poor linearity, and unsatisfactory PAE.

Examples of RF communication systems with one or more power amplifiers include, but are not limited to, mobile phones, tablets, base stations, network access points, customer-premises equipment (CPE), laptops, and wearable electronics. For example, in wireless devices that communicate using a cellular standard, a wireless local area network (WLAN) standard, and/or any other suitable communication standard, a power amplifier can be used for RF signal amplification. An RF signal can have a frequency in the range of about 30 kHz to 300 GHz, such as in the range of about 410 MHz to about 7.125 GHz for fifth generation (5G) communications in Frequency Range 1 (FR1).

### SUMMARY

According to one example, there is provided a Doherty power amplifier comprising: an input configured to receive an input signal to be amplified and to split the input signal into a first portion and a second portion, the input signal having an operating frequency; a carrier amplifier path coupled to the input to receive the first portion, the carrier amplifier path including a carrier amplifier coupled to a differential inverter, the carrier amplifier being configured to amplify the first portion and provide an amplified first portion to the differential inverter, the differential inverter having a capacitance configured to make the differential inverter behave as a short circuit at odd harmonics of the operating frequency, the capacitance coupling a first path and a second path of the differential inverter in parallel; and a peaking amplifier path coupled to the input to receive the second portion and comprising a peaking amplifier configured to amplify the second portion.

In one example the capacitance may be configured to make the differential inverter behave as an open circuit at the second harmonic of the operating frequency and as a short circuit at the third harmonic of the operating frequency.

In one example the carrier amplifier may be a class inverse F amplifier.

In one example the carrier amplifier and the peaking amplifier may be configured to operate as push-pull amplifiers.

In one example the first path and the second path may correspond to the push path and the pull path of the carrier amplifier respectively.

In one example the capacitance may be configured to provide a phase shift to the amplified first portion. In one example the phase shift is a 90 degree phase shift.

In one example the first path and the second path may each include an inductance, and the differential inverter may further include a second capacitance coupling the first path and the second path in parallel and being located after each of the inductances of the first path and the second path.

In one example the differential inverter may be configured to output an inverted amplified first portion and the Doherty power amplifier may further comprise a balanced to unbalanced matching circuit.

In one example the carrier amplifier path may comprise a carrier amplifier path output configured to output an inverted amplified first portion and the peaking amplifier path may comprise a peaking amplifier output configured to output an amplified second portion.

In one example the Doherty power amplifier may further comprise a combiner coupled to the carrier amplifier path output and the peaking amplifier path output and being configured to combine the inverted amplified first portion and the amplified second portion to yield an amplified radio-frequency signal.

According to another example, there is provided a method for amplifying a radio-frequency signal, the method comprising: receiving a radio-frequency signal at an input of a Doherty power amplifier, the radio-frequency signal having an operating frequency; splitting the input signal into a first portion and a second portion; providing the first portion to a carrier amplifier path and the second portion to a peaking amplifier path; amplifying the first portion at a carrier amplifier on the carrier amplifier path and providing an amplified first portion to a differential inverter on the carrier amplifier path, the differential inverter having a capacitance making the differential inverter behave as a short circuit at odd harmonics of the operating frequency, the capacitance coupling a first path and a second path of the differential inverter in parallel; and amplifying the second portion at a peaking amplifier on the peaking amplifier path to provide an amplified second portion.

In one example the capacitance may make the differential inverter behave as an open circuit at the second harmonic of the operating frequency and as a short circuit at the third harmonic of the operating frequency.

In one example the carrier amplifier may be a class inverse F amplifier.

In one example the carrier amplifier and the peaking amplifier operate as push-pull amplifiers.

In one example the first path and the second path may correspond to the push path and the pull path of the carrier amplifier respectively.

In one example the capacitance may provide a phase shift to the amplified first portion. In one example the phase shift is a 90 degree phase shift.

In one example the first path and the second path may each include an inductance, and the differential inverter may further include a second capacitance coupling the first path and the second path in parallel and being located after each of the inductances of the first path and the second path.

In one example the differential inverter may be configured to output an inverted amplified first portion and the Doherty power amplifier further comprises a balanced to unbalanced matching circuit configured to balance the inverted amplified first portion and the amplified second portion.

In one example the carrier amplifier path may comprise a carrier amplifier path output configured to output an inverted amplified first portion and the peaking amplifier path may comprise a peaking amplifier output configured to output an amplified second portion.

In one example the Doherty power amplifier may further comprise a combiner coupled to the carrier amplifier path output and the peaking amplifier path output and being configured to combine the inverted amplified first portion and the amplified second portion to yield an amplified radio-frequency signal.

According to another example, there is provided a power amplifier module comprising: a packaging substrate configured to receive a plurality of components; a Doherty power amplifier implemented on the packaging substrate, the Doherty power amplifier comprising: an input configured to receive an input signal to be amplified and to split the input signal into a first portion and a second portion, the input signal having an operating frequency; a carrier amplifier path coupled to the input to receive the first portion, the carrier amplifier path including a carrier amplifier coupled to a differential inverter, the carrier amplifier being configured to amplify the first portion and provide an amplified first portion to the differential inverter, the differential inverter having a capacitance configured to make the differential inverter behave as a short circuit at odd harmonics of the operating frequency, the capacitance coupling a first path and a second path of the differential inverter in parallel; and a peaking amplifier path coupled to the input to receive the second portion and comprising a peaking amplifier configured to amplify the second portion.

In one example the packaging substrate comprises a semiconductor die. In one example the capacitance is implemented on-die. In one example, the capacitance is not a surface-mount technology (SMT) capacitor.

In one example, the Doherty power amplifier comprises a supply system configured to provide a high-voltage supply signal, and the Doherty power amplifier is configured to receive the high-voltage supply signal and amplify the input signal.

According to another example, there is provided a wireless device having a transceiver configured to generate a radio-frequency input signal, and a front-end module in communication with the transceiver. The front-end module includes a packaging substrate configured to receive a plurality of components, and a Doherty power amplifier implemented on the packaging substrate, the Doherty power amplifier comprising: an input configured to receive the input signal to be amplified and to split the input signal into a first portion and a second portion, the input signal having an operating frequency; a carrier amplifier path coupled to the input to receive the first portion, the carrier amplifier path including a carrier amplifier coupled to a differential inverter, the carrier amplifier being configured to amplify the first portion and provide an amplified first portion to the differential inverter, the differential inverter having a capacitance configured to make the differential inverter behave as a short circuit at odd harmonics of the operating frequency, the capacitance coupling a first path and a second path of the differential inverter in parallel; and a peaking amplifier path coupled to the input to receive the second portion and comprising a peaking amplifier configured to amplify the second portion.

In some examples, the Doherty power amplifier comprises a supply system configured to provide a high-voltage supply signal, and the Doherty power amplifier is configured to receive the high-voltage supply signal and amplify the input signal.

In some examples, the Doherty power amplifier further includes an output path configured to receive and route an amplified radio-frequency input signal to a filter.

In some examples, the wireless device comprises an antenna in communication with the front-end module and configured to transmit the amplifier radio-frequency input signal.

Examples of the present disclosure provide an improved Doherty power amplifier, a method for amplifying a radio-frequency signal, and a power amplifier module. In particular, a Doherty power amplifier according to the present disclosure (and corresponding method and power amplifier module) allows for lower voltage swing at the carrier amplifier, improved ruggedness, healing of amplitude variation-phase deviation (AMPM) soft compression, improved linearity, better adjacent channel leakage ratio (ACLR) symmetry, and improved power added efficiency (PAE) (when compared with existing Doherty power amplifiers), all of which are described in more detail below.

Still other aspects and advantages of these examples are discussed in detail below. Examples disclosed herein may be combined with other examples in any manner consistent with at least one of the principles disclosed herein, and references to “an example,” “some examples,” “an alternate example,” “various examples,” “one example” or the like are not necessarily mutually exclusive and are intended to indicate that a particular feature, structure, or characteristic described may be included in at least one example. The appearances of such terms herein are not necessarily all referring to the same example.

### BRIEF DESCRIPTION OF THE DRAWINGS

Various aspects of at least one example are discussed below with reference to the accompanying figures, which are not intended to be drawn to scale. The figures are included to provide illustration and a further understanding of the various aspects and examples, and are incorporated in and constitute a part of this specification, but are not intended as a definition of the limits of the invention. In the figures, each identical or nearly identical component that is illustrated in various figures is represented by a like numeral. For purposes of clarity, not every component may be labeled in every figure. In the figures:

FIG. 1 is a circuit diagram of a Doherty power amplifier according to an example;

FIG. 2 is a circuit diagram of a Doherty power amplifier according to an example;

FIG. 3A is a circuit diagram of a differential inverter according to an example;

FIG. 3B is a circuit diagram of a differential inverter according to an example;

FIG. 4A is a series of Smith charts illustrating harmonic termination in an amplifier according to an example;

FIG. 4B is a series of Smith charts illustrating harmonic termination in an amplifier according to an example;

FIG. 5A is a graph comparing performance of amplifiers according to an example;

FIG. 5B is a graph comparing performance of amplifiers according to an example;

FIG. 5C is a graph comparing performance of an amplifier according to an example;

FIG. 5D is a graph comparing performance of an amplifier according to an example;

FIG. 6A is a graph comparing AMPM distortion of amplifiers according to an example;

FIG. 6B is a graph comparing AMAM distortion of amplifiers according to an example;

FIG. 7A is a graph illustrating collector waveforms in the time domain for an amplifier according to an example;

FIG. 7B is a graph illustrating real time voltage swing for an amplifier according to an example;

FIG. 7C is a graph illustrating collector waveforms in the time domain for an amplifier according to an example;

FIG. 7D is a graph illustrating real time voltage swing for an amplifier according to an example;

FIG. 8 is a graph comparing current usage of amplifiers according to an example;

FIG. 9A is a graph comparing linearity of amplifiers according to an example;

FIG. 9B is a graph comparing power added efficiency of amplifiers according to an example;

FIG. 10 is a graph comparing performance of amplifiers according to an example;

FIG. 11A is a graph comparing performance of amplifiers according to an example;

FIG. 11B is a graph comparing ACLR of amplifiers according to an example;

FIG. 12A is a graph comparing performance of amplifiers according to an example;

FIG. 12B is a graph comparing performance of amplifiers according to an example;

FIG. 13 is a schematic block diagram of a module according to an example;

FIG. 14 is a schematic block diagram of a module according to an example;

FIG. 15 is a schematic block diagram of a module according to an example; and

FIG. 16 is a schematic diagram of a wireless device according to an example.

### DETAILED DESCRIPTION

Aspects and examples described herein are directed to a Doherty power amplifier for providing lower voltage swing at the carrier amplifier, improved ruggedness, healing of AMPM soft compression, improved linearity, better adjacent channel leakage ratio (ACLR) symmetry, and improved power added efficiency (PAE) when compared with existing Doherty power amplifiers.

Power amplifiers, for example Doherty power amplifiers, may be designed to be applicable to a broad frequency range. For some applications, for example in some 5G New Radio (NR) devices, this broad frequency range applicability may not be as necessary. Modifications to existing Doherty amplifiers may be made in order to improve many aspects of their performance. In certain implementations, communications are supported using 5G NR technology over one or more frequency bands that are less than 6 Gigahertz (GHz), for example 5 GHz, and/or over one or more frequency bands that are greater than 6 GHz. For example, the communication links can serve FR1, Frequency Range 2 (FR2), a combination thereof, and so forth.

Examples of the methods and apparatuses discussed herein are not limited in application to the details of construction and the arrangement of components set forth in the following description or illustrated in the accompanying drawings. The methods and apparatuses are capable of implementation in other examples and of being practiced or of being carried out in various ways. Examples of specific implementations are provided herein for illustrative purposes only and are not intended to be limiting. Also, the phraseology and terminology used herein is for the purpose of description and should not be regarded as limiting. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms.

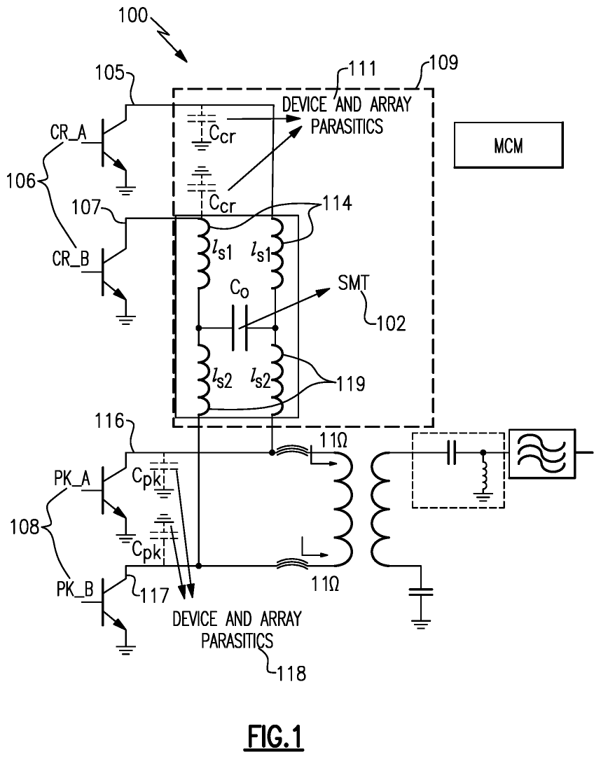

Examples of the present disclosure will be described with reference to the accompanying figures. In particular, examples of the Doherty power amplifier according to aspects of the present invention will be described often by comparison with a reference Doherty power amplifier design. Such a reference Doherty power amplifier is illustrated in FIG. 1.

FIG. 1 illustrates a circuit diagram of a reference Doherty power amplifier 100 according to an example. Referring to FIG. 1, the Doherty power amplifier 100 includes an input to receive and split a radio-frequency signal having an operating frequency into separate portions which are directed respectively along signal paths corresponding to a carrier amplifier path and a peaking amplifier path.

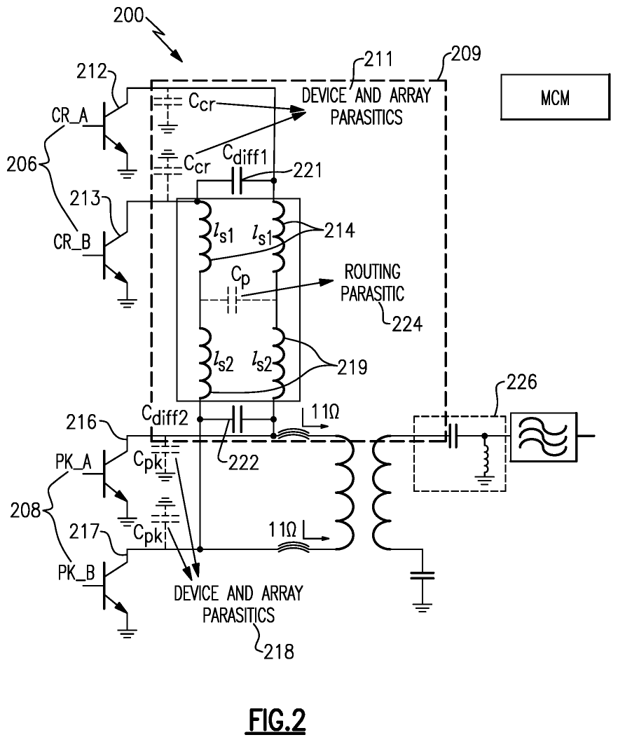

The carrier amplifier path comprises a carrier amplifier 106, which outputs an amplified signal portion to a differential inverter 109. The differential inverter 109 provides a phase shift to the portion of the signal travelling along the carrier amplifier path 105 shifting the phase relative to the portion traveling on the peaking amplifier path 107. The differential inverter circuit is further illustrated in FIG. 3A.

The carrier amplifier 106 and the differential inverter 109 may form an arrangement resembling a class E amplifier design in operation. The carrier amplifier 106 operates as a push-pull amplifier. That is, the carrier amplifier 106 comprises a positive path 105 and a negative path 107, corresponding to positive and negative paths of the differential inverter.

The carrier amplifier may comprise an array of transistors, for example field-effect transistors. The differential inverter 109 comprises capacitance C_{cr} 111. This capacitance is the parasitic capacitance arising from the transistor array of the amplifier and from device connections. Typically, the value of this capacitance is relatively small. For example, at a 5 GHz fundamental frequency, the capacitance may be approximately 0.4 pF. The differential inverter 109 also comprises a first inductance lₛ₁ 114 on each of the positive 105 and negative 107 paths of the inverter.

The differential inverter 109 further comprises a capacitance C₀ 102, which is implemented as a surface-mount technology (SMT) capacitor. The positive 105 and negative 107 paths of the differential inverter 109 also each comprise a second inductance lₛ₂ 119. As the inverter is a differential inverter, the paths may be approximately symmetrical and therefore lₛ₁ and lₛ₂ may respectively have the substantially similar or identical values.

The inductances may be constructed by bond wires and multichip module (MCM) routing. The inductance may therefore depend on the length of the bond wires and distance of routing. Assuming a fundamental frequency of 5 GHz, the total inductance of the class E amplifier may be approximately 1.3 nH, for example 1.29 nH.

The Doherty amplifier 100, and in particular the peaking amplifier path, comprises a peaking amplifier 108. Similarly to the carrier amplifier 106, the peaking amplifier 108 operates as a push-pull amplifier and comprises a positive 116 and negative path 117. The amplifier may also comprise a transistor array, and capacitance Cₚₖ 118 is a parasitic capacitance deriving from the transistor array and device connections. The capacitance 118 is comprised within a balanced to unbalanced (BALUN) matching circuit.

As described above, for 5G networks, a fundamental frequency fo of around 5 GHz may be used. To ensure proper working of the carrier amplifier, the carrier amplifier sees a proper load length at fundamental frequency, and first and second harmonics of the fundamental frequency.

When applying this frequency as the operational frequency to the existing Doherty amplifier 100 implementing a class E carrier amplifier operation, the common mode second harmonic frequency (2f₀) component sees the capacitance C_{cr} 111, as well as the inductance lₛ₁ 114. In other words, at this frequency, the capacitance 111 and inductance 114 form a large impedance for this frequency component, thereby blocking the signal; that is, the circuit can be considered an open circuit. An “open circuit” is considered to be a circuit with a very high or infinite impedance between two nodes. While the impedance formed by the capacitor and inductance is not infinite in practice, the impedance can be considered to have formed an open circuit.

The third harmonic frequency component (3f₀) similarly sees the capacitance 111 and inductance 114 which, again, form a large impedance. The 3f₀ component of the signal therefore also terminates with an open circuit due to the large impedance.

Therefore, in the reference class E amplifier design of FIG. 1, both the second and third harmonic components see large impedances and lead to an open circuit. As described in more detail below, however, the reference class E design amplifier may exhibit poor linearity, significant AMPM soft compression, poor PAE, poor ruggedness, and significant voltage swing.

FIG. 2 illustrates a Doherty power amplifier 200 according to an example. The Doherty power amplifier 200 comprises an input configured to receive an input signal to be amplifier and to split the input signal into a first portion and a second portion. Such an input signal may be partially amplified by a pre-driver amplifier (not shown) before being divided into the first and second portions. The input signal has an operating frequency, which in this example may be approximately 5 GHz. The first portion and the second portion of the signal are respectively provided to a carrier amplifier path and a peaking amplifier path.

The carrier amplifier path comprises a carrier amplifier 206 coupled to the input (not shown) to receive the first portion of the signal, and the carrier amplifier 206 is configured to amplify the first portion of the signal. The carrier amplifier 206 is coupled to a differential inverter 209. Having amplified the first portion, the carrier amplifier 206 outputs the amplified first portion to the differential inverter 209.

The differential inverter 209 circuit is further illustrated in FIG. 3B. The differential inverter 209 provides a phase shift to the amplified first portion travelling along the carrier amplifier path shifting the phase relative to the portion travelling on the peaking amplifier path. In this example, the phase shift is approximately 90 degrees.

The carrier amplifier 206 operates as a push-pull amplifier and comprises a first (positive) 212 and second (negative) 213 path corresponding to positive and negative paths of the differential inverter.

The Doherty amplifier 200 comprises the parasitic capacitance Ccr 211 arising from the transistor array and device connections. That is, the carrier amplifier may comprise an array of transistors, for example field-effect transistors, giving rise to a parasitic capacitance.

In various examples, the design of the carrier amplifier and differential inverter 209 forms an arrangement resembling a class inverse F operation mode on the carrier amplifier in operation. The amplifier of the present invention, and indeed inverse class F amplifiers, use open conditions at even harmonics and short circuited conditions at the odd harmonics.

In this example, a SMT implemented capacitor C₀, such as that illustrated in connection with the class E amplifier design, is not present. Instead, capacitors C_{diff1} 221 and C_{diff2} 222 have been included at each end of the differential inverter 209. These capacitors couple the first (positive) 212 path and the second (negative) 213 path of the differential inverter in parallel, and may be much larger in value than the parasitic capacitance 211. These capacitors may advantageously be implemented on-die, or on substrate. For example, the Doherty amplifier 200 may be implemented in a radio-frequency module implemented on a packaging substrate comprising a semiconductor die such as a silicon die. The capacitors may be implemented on-die, or on substrate. In this way, an SMT component is removed (the capacitor removed from the class E design) thereby saving cost. In some examples, the capacitors may be implemented as SMT components, rather than being implemented on-die. In addition, in some examples, the capacitor C₀ is not removed, but is included in addition to the capacitors C_{diff1} and C_{diff2}.

The differential inverter 209 further comprises inductance lₛ₁ 214 and lₛ₂ 219 on each path of the differential inverter 209. The differential inverter 209 may be symmetrical such that the values of the inductances on each path are approximately equal. The inductances are illustrated as multiple inductors on each path. This is to highlight the absence of the SMT capacitor relative to the class E design. However, the inductors may be formed by a single inductance in some examples.

The inductances are constructed by bond wires and multichip module (MCM) routing, for example on a radio-frequency integrated circuit (RFIC), and the inductances therefore depend on the length of the bond wires and distance of routing. By removing the SMT capacitor, the bond wires and routing paths can be made shorter. In this way, the inductance may be reduced and the signal paths advantageously become less lossy as the limited Q of the inductor is smaller, leading to a higher PAE. Assuming a fundamental frequency of 5 GHz, the total inductance of the class inverse F design may be approximately 0.7 nH, for example 0.73 nH. This is approximately 60% of the total inductance of the class E amplifier design.

The differential inverter 209 may also include a parasitic capacitance Cₚ 224 arising from routing parasitics.

The Doherty amplifier 200, and in particular the peaking amplifier path, comprises a peaking amplifier 208. The peaking amplifier 208 also operates as a push-pull amplifier having a positive 216 and negative 217 path. The peaking amplifier 208 is coupled to the input to receive the second portion of the signal, and the peaking amplifier 208 is configured to subsequently amplify the second portion to provide an amplified second portion. In some examples, the peaking amplifier 208 is configured only to conduct on the peaks of the input signal. That is, the peaking amplifier 208 only operates when it is required to do so. The carrier amplifier 206 runs constantly, the peaking amplifier 208 enters operation only when the carrier amplifier starts to run into compression.

The carrier amplifier path comprises an output configured to output the amplified and phase-shifted, or inverted, first portion. The peaking amplifier path also comprises an output configured to output the amplified second portion.

The peaking amplifier 208 may similarly comprise a transistor array and capacitance Cₚₖ 218. The capacitance 218 is a parasitic capacitance deriving from the transistor array and device connections. The capacitance 218 is comprised within a balanced to unbalanced (BALUN) matching circuit having a first coil and a second coil. The BALUN circuit receives amplifier signals from the carrier amplifier path and peaking amplifier path and is configured to balance the amplified first portion of the signal phase shifted, or inverted, by the differential inverter on the carrier amplifier path with the amplified second portion from the peaking amplifier path.

The Doherty power amplifier 200 further comprises a combiner 226 coupled to the carrier amplifier path output and the peaking amplifier path output. The combiner 226 is configured to combine the phase-shifted amplified first portion with the amplified second portion to yield an amplified radio-frequency signal.

To ensure proper working of the carrier amplifier, it is important that the carrier amplifier sees a proper load length at fundamental frequency, and at first and second harmonics of the fundamental frequency. For this example and for comparison with the existing class E amplifier design discussed above, 5 GHz will be considered as the fundamental operating frequency.

When applying this frequency as the operation frequency to the Doherty amplifier 200 implementing the class inverse F amplifier, the common mode second harmonic frequency (2f₀) component sees the capacitance 211 and inductance 214, which may present a relatively large impedance, but does not see the capacitance 221 due to its larger value. Similarly to the class E design, the termination of the second harmonic component is still an open circuit due to the large impedance from capacitance 211 and inductance 214.

However, the third harmonic frequency component of the operational frequency may be treated differently by the class inverse F design than the class E design. The third harmonic frequency component (3f₀) again sees the parasitic capacitance 211, but additionally also now sees the capacitance C_{diff1} 221. This capacitor 221 allows a relatively low impedance at this frequency component. For example, the impedance may be 0.3 times the fundamental load length. This small impedance is wideband. Due to this low impedance, the capacitor C_{diff1} 221 acts to short the circuit. It will be understood that a short circuit means that current may travel with no, or very low, impedance. The carrier amplifier 206 therefore terminates the second harmonic component as an open circuit, and the termination of the third harmonic component is a short circuit. Doing so provides a number of advantages which are discussed in detail below. For example, the Doherty amplifier 200 provides improved linearity, healing of AMPM soft compression, improved PAE, improved ruggedness, and reduced voltage swing.

The remaining routing parasitic capacitance 224 may be relatively small, for example, 0.1 pF, and its contribution to the phase shift is very little.

The Doherty amplifier 200 having one or more features as described herein may be applied to a method for amplifying a radio-frequency signal. The method for amplifying a radio-frequency signal comprises first receiving a radio-frequency signal at an input of the Doherty power amplifier 200, the radio-frequency signal having an operating frequency. The signal is then split into a first portion and a second portion, the first portion being provided to the carrier amplifier path and the second portion being provided to the peaking amplifier path.

The carrier amplifier 206 on the carrier amplifier path amplifies the first portion and provides the amplified first portion to the differential inverter 209 on the carrier amplifier path. The differential inverter 209 comprises the capacitance 221 making the differential inverter 209 behave close to a short circuit, or as a short circuit, at odd harmonic frequencies of the operating frequency. That is, the current is allowed to travel through the capacitance 221 with little or no impedance. The capacitance 221 couples the first and second paths of the differential inverter 209. The peaking amplifier 208 on the peaking amplifier path amplifies the second portion to provide an amplified second portion.

Any of the examples of the Doherty amplifier described may be applicable to the method for amplifying the radio-frequency signal.

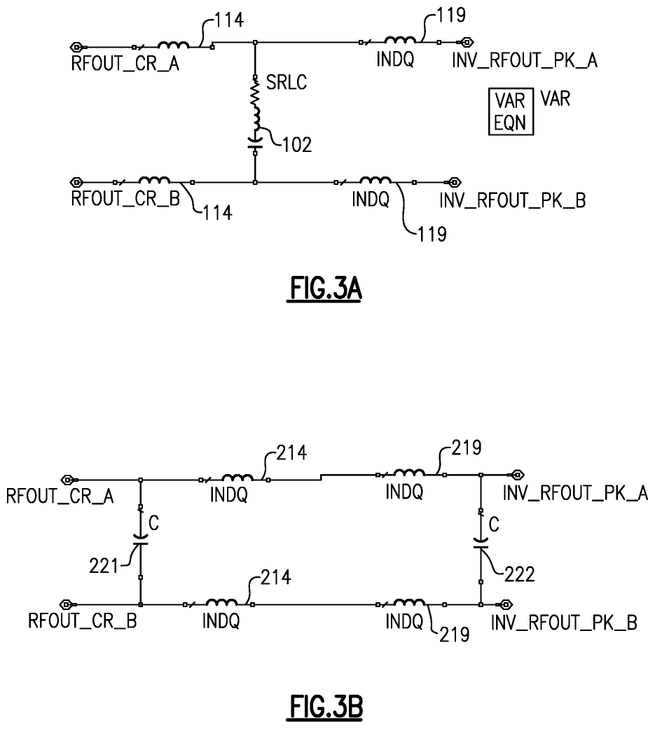

FIG. 4A illustrates a series of Smith charts showing the load length seen by the carrier power amplifier 110 of FIG. 1. The Smith charts show terminations at the second harmonic frequency (2f₀) and the third harmonic frequency (3f₀) for both the push and pull paths equivalent to the positive 105 and negative 107 sides of the carrier amplifier 106 respectively. For the reasons explained above, at the second harmonic frequency of the operating frequency, the signal sees the parasitic capacitance (which may present, for example, an open circuit) and the series inductance which forms a high impedance on both the positive and negative sides of the amplifier.

Similarly, at the third harmonic frequency of the operating frequency, the signal sees the parasitic capacitance from the carrier array (which may present, for example, an open circuit). The signal may still be blocked by the inductance (open circuit), which presents a high impedance termination on both the positive 105 and negative 107 paths.

FIG. 4B illustrates a series of Smith charts showing the load length seen by the carrier power amplifier 206 of FIG. 2. This carrier power amplifier may be operating as a class inverse F amplifier. The Smith charts show terminations at the second harmonic frequency and the third harmonic frequency for both the push and pull paths equivalent to the positive 212 and negative 213 sides of the carrier amplifier 206 respectively.

At the second harmonic frequency of the operating frequency, similarly to in the class E power amplifier of FIG. 1, both the positive 212 and negative 213 sides of the push pull amplifier terminate as an open circuit. The second harmonic frequency signal sees the parasitic capacitance 211 and the differential inverter inductance 214, but does not see the first differential inverter capacitor C_{diff1} 221. Therefore, the second harmonic frequency component of the operation frequency terminates as an open circuit.

However, at the third harmonic frequency of the operating frequency, the signal sees the first differential inverter capacitor C_{diff1} 221, which are much larger in capacitance than the parasitic capacitance from the carrier array due to the removal of the differential inverter capacitance C₀ 102 in the class E amplifier design. Therefore, at the third harmonic frequency, the capacitor C_{diff1} 221 allows a low impedance, which can be regarded as a short impedance which shorts the circuit. For example, the impedance may be approximately 0.3 times the fundamental load.

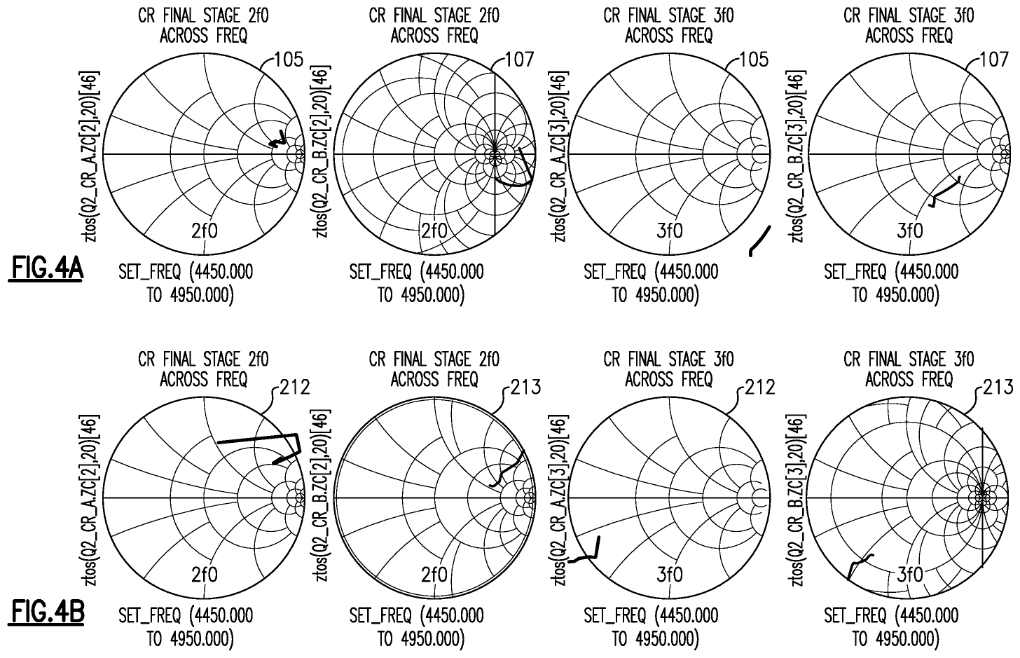

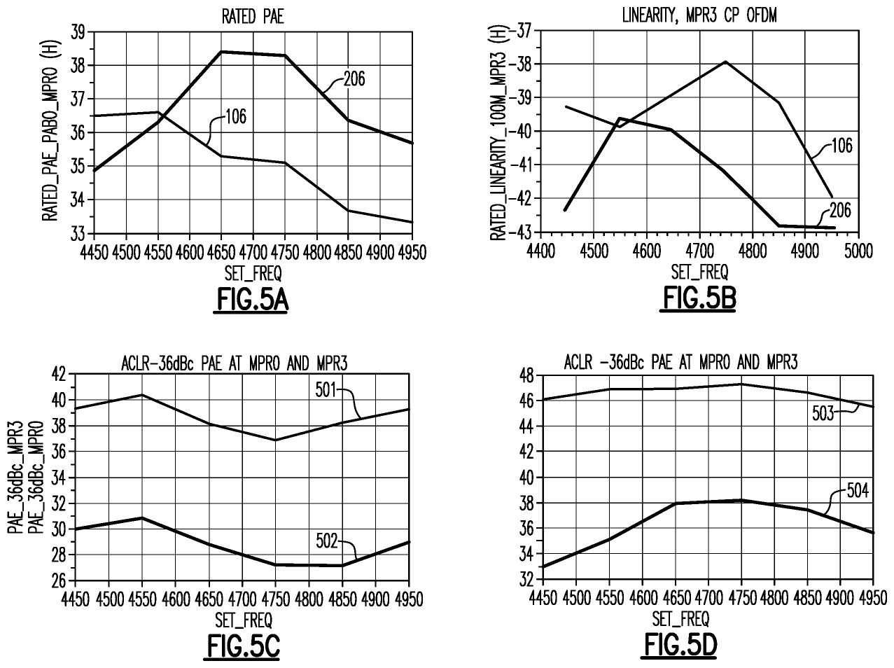

FIG. 5A illustrates a graph showing the PAE performance of the class E amplifier in comparison with the class inverse F amplifier across a frequency range. Across the majority of the frequency range, and as the frequency approaches 5 GHz, the PAE of the class inverse F carrier amplifier 206 is improved when compared to the class E amplifier design 106. This simulation is tested at the same MPR0 or average power.

FIG. 5B illustrates a graph showing the linearity performance of the class E amplifier in comparison with the class inverse F amplifier across a frequency range. Across almost all of the frequency range, and in particular as the frequency approaches 5 GHz, the linearity is improved in the inverse F class amplifier 206 when compared with the class E design 106.

FIG. 5C illustrates a graph showing the linear PAE of the existing class E amplifier with MPR0 (PAR=4.5 dB) (average power level) 501 and MPR3 (PAR=7.5) stimulus 502. The linear PAE demonstrates the maximum PAE that the amplifier is able to amplify linearly. FIG. 5D is a corresponding graph illustrating the linear PAE of the class inverse F amplifier with MPR0 (average power level) 503 and MPR3 504. The inverse F class amplifier shows improved percentage at both MPR0 and MPR3, demonstrating higher linear efficiency.

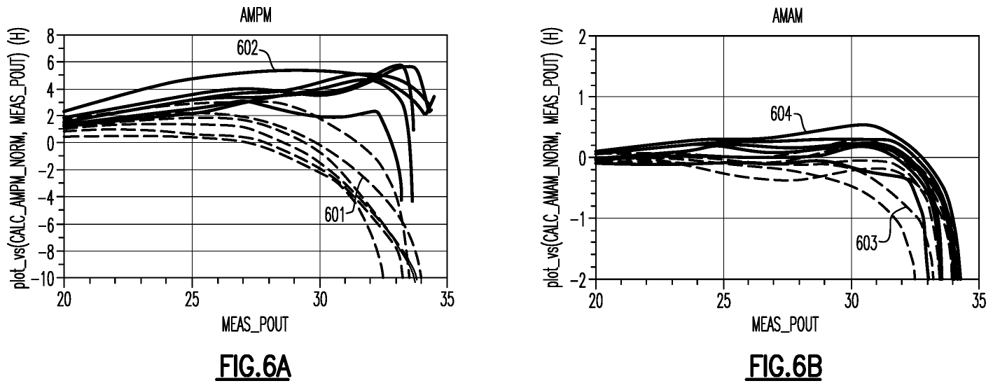

FIG. 6A illustrates a graph showing a comparison of AMPM distortion in the class E amplifier 601 with the class inverse F amplifier 602 across a power range. Multiple frequencies for each amplifier are shown. AMPM distortion is an unwanted phase modulation of the radio-frequency output carrier due to the modulation of the supply voltage. Some amplifiers, such as class E amplifiers, may exhibit significant soft AMPM distortion. Examples of the disclosure may provide amplifiers with improved AMPM distortion. For example, certain example class inverse F amplifiers may provide a more linear phase, such that the amplifiers are capable of delivering more linear power.

FIG. 6B illustrates a graph showing a comparison of the difference between the supply voltage and the envelope of the RF output voltage (AMAM distortion) in the class E amplifier 603 with the class inverse F amplifier 604 across a power range. The inverse F class amplifier may be subject to similar AMAM distortion as the class E amplifier.

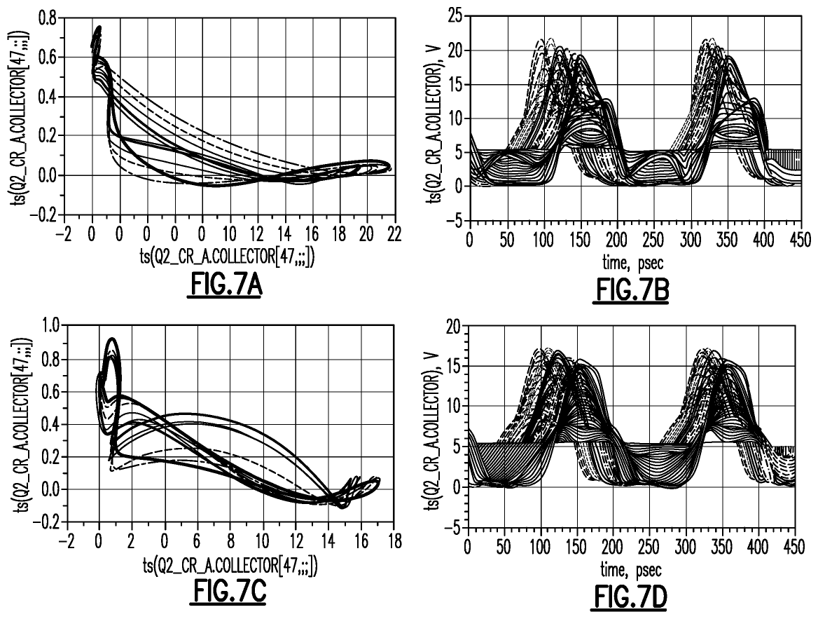

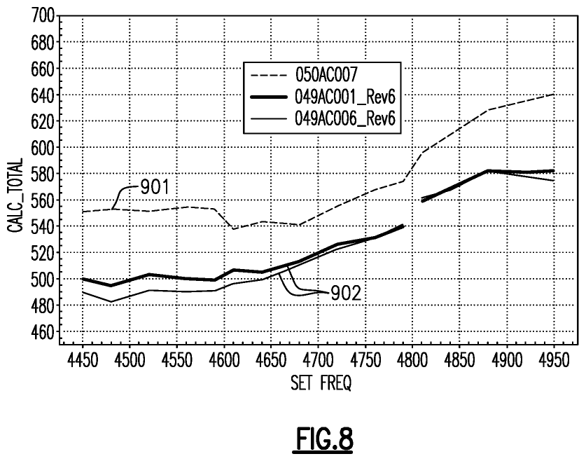

FIG. 7A illustrates a graph showing a collector wave form in the time domain for a class E amplifier. Collector current is shown as a function of collector voltage showing the instantaneous load line. At a certain time and a certain power range, the voltage swing can reach over 20 V, and almost 22 V. The voltage swing may be a metric of interest as the higher voltage swing may contribute to the soft AMPM compression exhibited by the class E amplifier seen in FIG. 6A. FIG. 7B is a graph illustrating the real time voltage swing for the class E amplifier, again showing that the voltage swing can reach over 20 V.

In contrast, FIG. 7C illustrates a graph showing a collector wave form in the time domain for a class inverse F amplifier. Again, collector current is shown as a function of collector voltage showing the instantaneous load line. The class F amplifier exhibits a lower voltage swing than the class E amplifier. In particular, the maximum voltage swing reaches less than 17 V under the same conditions. This lower voltage swing helps to heal the AMPM soft compression. This is additionally shown in the graph of FIG. 7D illustrating the real time voltage swing, again showing that the voltage swing does not reach 17 V. Furthermore, the lower voltage swing on collection at the transistor allows the amplifier to be more rugged.

The Doherty power amplifier 200 having one or more features as described herein can be implemented in a power amplifier module. Such a module can be, for example, a front-end module (FEM). A radio-frequency module may incorporate the Doherty power amplifier. In some examples, the module includes a packaging substrate, which comprises a semiconductor die.

In some examples, a class E amplifier is also included in the radio-frequency module. Some examples may not include the class E amplifier. The class E amplifier may include a capacitor Cp situated in the middle of a balanced to unbalanced (BALUN) circuit. This capacitor is implemented as a surface-mount technology (SMT) capacitor.

In some examples, the radio-frequency module also comprises a Doherty power amplifier configured as a class inverse F carrier amplifier. In various examples, an SMT capacitor may be omitted in the middle of the differential inverter circuit for the class inverse F amplifier. For example, this SMT capacitor may be replaced in the inverse F class amplifier arrangement discussed herein. The carrier amplifier may instead include capacitors which are implemented on-die. In this way, the amplifier arrangement may obviate an SMT component (for example, an SMT capacitor), which may reduce a cost of production where SMT capacitors are more expensive than on-die capacitors.

The class inverse F amplifier comprises a differential inverter, having a first path comprising a bond wire (the positive carrier amplifier path), a routing wire, and another bond wire (the positive peaking amplifier path). The differential inverter also comprises a second path comprising a bond wire (the negative carrier amplifier path), a routing wire, and another bond wire (the negative peaking amplifier path). The bond wires may have a height of approximately 125 μm. As the capacitors are located on-die and there is no capacitor implemented as an SMT in the differential inverter, the routing wires can be made shorter in comparison to the corresponding wires in a class E amplifier. In doing so, the paths are shortened and the inductance on the routing wires is reduced. This allows the paths to be less lossy and improve performance and the PAE of the amplifier.

In some implementations, the module having one or more features described herein can be included in a radio-frequency device such as a wireless device. Such a module can be implemented directly in the wireless device, in a module form, or in some combination thereof. In some examples, such a wireless device can non-exhaustively include, for example, a cellular phone, a smart-phone, a hand-held wireless device with or without phone functionality, or a wireless tablet.

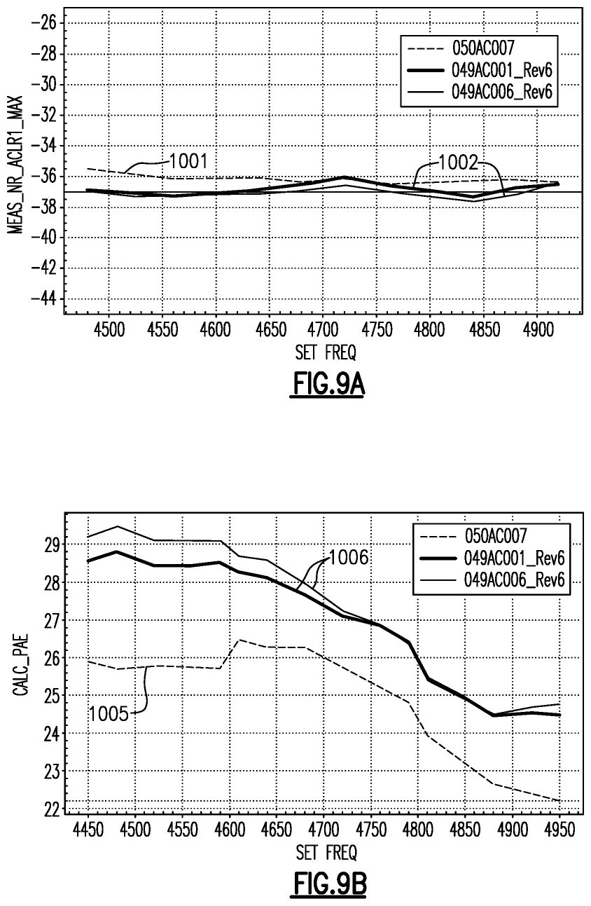

FIG. 8 illustrates a graph showing current usage at MPR0 (average power) of 27 dBm, showing the class E amplifier 901 as described above and the Doherty amplifier 902. At least in part due to the implementation of capacitors 221 and 222 in place of the capacitor Cp 102 of the class E amplifier, the inverse F class carrier amplifier draws much less current. At the example power level, the inverse F class arrangement saves up to 60 mA when compared to the class E design. For consistency, two inverse F class amplifiers 902 were tested.

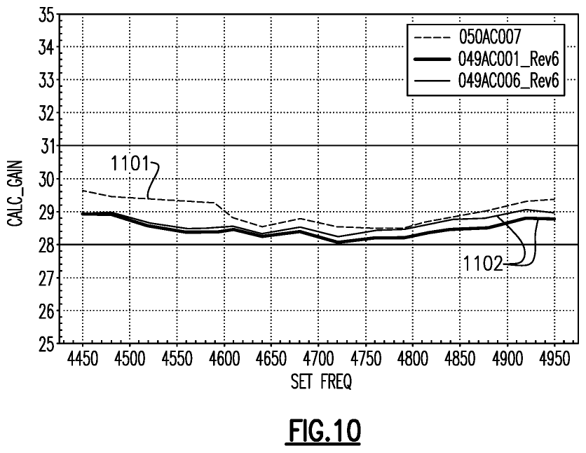

FIG. 9A illustrates a graph showing a comparison of linearity between a class E amplifier 1001 and a class inverse F carrier amplifier 1002 at a power (MPR3) of 24 dBm. With corresponding optimum bias of both Class E and inverse F amplifiers, the class inverse F amplifier advantageously exhibits at least a 1 dB better linearity than the class E amplifier with up to 60 mA less total current usage. Again, for consistency, two inverse F class amplifiers 1002 were tested. The arrangement provided (as will be discussed more below) demonstrates a very good adjacent channel leakage ratio (ACLR).

FIG. 9B illustrates a graph showing the PAE at MPR0 or 27 dBm for the class E amplifier 1005 and the class inverse F carrier amplifier 1006. Again, for consistency, two inverse F class amplifiers 1006 were tested. Both tests demonstrate values consistent with one another. In addition, the PAE at MPR0 exhibited by the inverse F class carrier amplifier is significantly higher than the class E amplifier on both paths. For example, the inverse F class amplifier exhibits 2% higher PAE than class E. This improvement arises in part due to, as described above, the inductor path being shorter and the inductance being lower in the class inverse F arrangement when compared with the class E design, making the arrangement less lossy and therefore more efficient than, for example, class E carrier amplifiers.

FIG. 10 illustrates a graph showing the gain at MPR3 of the class E amplifier 1101 in comparison with the class inverse F amplifier 1102. Again, two class inverse F amplifiers 1102 are shown. Advantageously, the class inverse F amplifier can tolerate a lower bias for the same linearity, which contributes to an improved PAE over the class E amplifier design. Although gain may be reduced, the amplifier may still fall within a common specification window of between 28 and 31 dB while desirably having an improved PAE.

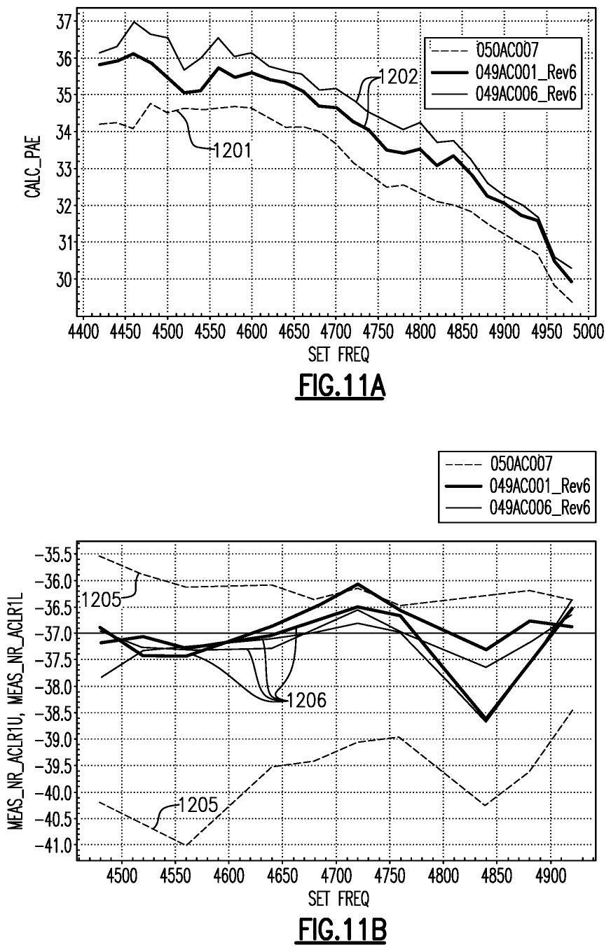

FIG. 11A illustrates a graph comparing PAE of the class E amplifier 1201 in comparison with the class inverse F amplifier 1202 (two tests shown) at Pₛₐₜ power level. At this power level, the class inverse F amplifier exhibits an improved PAE over the class E amplifier. In particular, an improvement of between 2% and 4% PAE is observed.

FIG. 11B illustrates a graph comparing the ACLR left and ACLR right of the class E amplifier 1205 in comparison with the class inverse F amplifier 1206. The ACLR of the class E amplifier exhibits a significant gap between the left and right paths, which may indicate that the PAE is experiencing heavy memory. At a power of 24 dBm, the class E amplifier experiences a 4 dBm gap between the ACLR left and ACLR right. However, advantageously, the class inverse F amplifier may experience a much smaller gap between the ACLR left and ACLR right, therefore showing improved ACLR symmetry, meaning memory usage is significantly reduced.

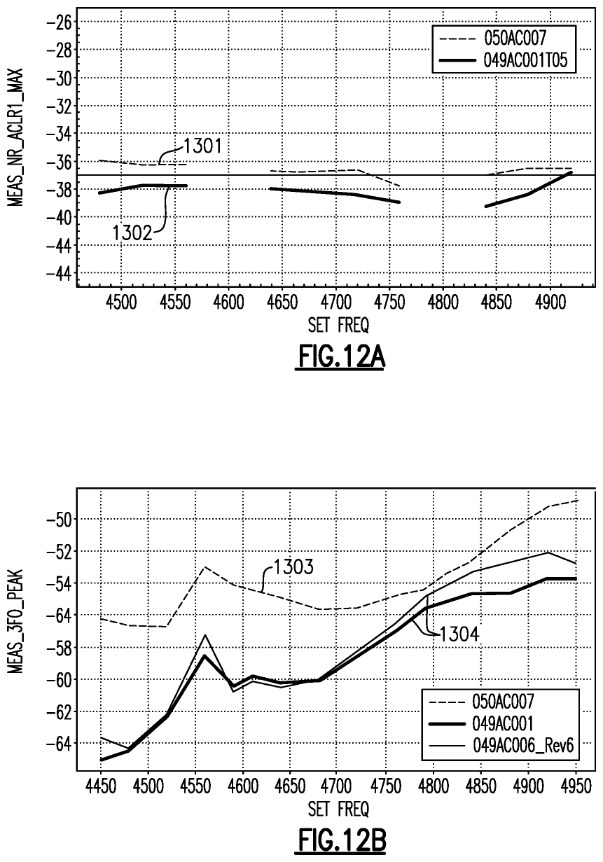

FIG. 12A illustrates a graph illustrating comparison of ACLR of the class E amplifier 1301 in comparison with the class inverse F amplifier 1302 under the same bias conditions. When applying the same bias to the class inverse F design as is applied to the existing class E design, the class inverse F design amplifier exhibits an improved linearity. In particular, the linearity at this bias is approximately 2 dBm better for the class inverse F design than for the class E design.

FIG. 12B illustrates a graph illustrating comparison of performance at the third harmonic of the operating frequency between the class E amplifier 1303 with the class inverse F amplifier 1304 (again, two class inverse F components were tested for consistency). All across the frequency band, it can be seen that the class inverse F amplifier shows lower third order harmonic power level which may be preferred by the system.

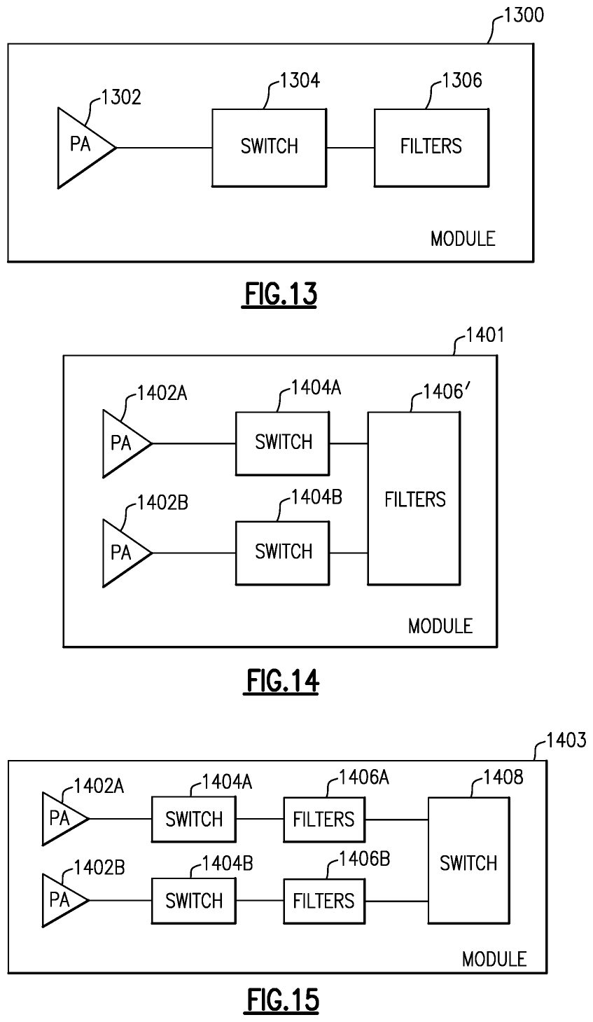

FIG. 13 illustrates a schematic block diagram of a module 1300 that includes a power amplifier 1302 such as a Doherty power amplifier implemented in accordance with one or more examples described herein. The module 1300 may be a power amplifier module and includes a switch 1304 and filters 1306. The module 1300 can include a package that encloses the illustrated components. The power amplifier 1302, the switch 1304, and the filters 1306 can be disposed on a common packaging substrate. The power amplifier 1302 can amplify a radio-frequency signal as described above. The switch can be a multi-throw radio-frequency switch. The switch 1304 can electrically couple an output of the power amplifier 1302 to a selected filter of the filters 1306. The filters 1306 may include any number of filters.

FIG. 14 illustrates a schematic block diagram of a module 1401 that includes power amplifiers 1402A and 1402B, switches 1404A and 1404B, and filters 1406′. One or both of the power amplifiers 1402A and 1402B may be implemented as Doherty power amplifiers in accordance with one or more examples described herein and having one or more advantageous features described herein. The module 1401 is similar to the module 1300 of FIG. 13 except that the module 1401 includes an additional power amplifier 1402B and an additional switch 1404B, and the filters 1406′ are arranged to filter signals for the signal paths associated with the power amplifiers 1402A and 1402B. The different signal paths may be associated with different frequency bands and/or different modes of operation (for example, different power modes, different signaling modes, and so forth).

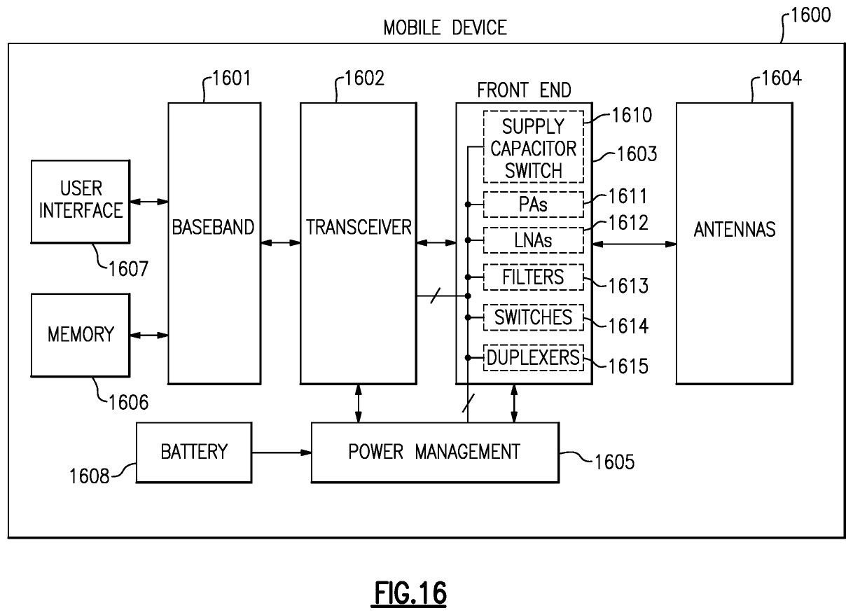

FIG. 15 illustrates a schematic diagram of a module 1403 that includes power amplifiers 1402A and 1402B, switches 1404A and 1404B, filters 1406A and 1406B, and an antenna switch 1408. Again, one or both of the power amplifiers 1402A and 1402B may be implemented as Doherty power amplifiers in accordance with one or more examples described herein and having one or more advantageous features described herein. The module 1403 is similar to that of FIG. 14, except that the module 1403 includes an antenna switch 1408 arranged to selectively couple a signal from the filters 1406A and 1406B to an antenna node. The filters 1406A and 1406B may correspond to the filters 1406′ of FIG. 14.

FIG. 16 illustrates a schematic diagram of one example of a wireless device, which may be a mobile device 1600. The mobile device 1600 includes a baseband system 1601, a transceiver 1602, a front-end system 1603, antennas 1604, a power-management system 1605, a memory 1606, a user interface 1607, and a battery 1608.

Although the mobile device 1600 illustrates one example of an RF system that can include one or more features of the present disclosure, the teachings herein are applicable to electronic systems implemented in a wide variety of ways.

The mobile device 1600 can be used for communication using a wide variety of communication technologies including, but not limited to, 2G, 3G, 4G (including LTE, LTE-Advanced, and LTE-Advanced Pro), 5G, WLAN (for instance, Wi-Fi), WPAN (for instance, Bluetooth and ZigBee), WMAN (for instance, WiMax), and/or GPS technologies, but may be particularly applicable to 5G technologies.

The transceiver 1602 generates RF signals for transmission and processes incoming RF signals received from the antennas 1604. Various functionalities associated with the transmission and receiving of RF signals can be achieved by one or more components that are collectively represented in FIG. 16 as the transceiver 1602. In one example, separate components (for instance, separate circuits or dies) can be provided for handling certain types of RF signals.

As shown in in FIG. 16, the transceiver 1602 is connected to the front-end system 1603 and to the power-management circuit 1605 using a serial interface. All or part of the illustrated RF components may be controlled by the serial interface to configure the mobile device 1600 during initialization and/or while fully operational. In another embodiment, the baseband processor 1601 is additionally or alternative connected to the serial interface and operates to configure one or more RF components, such as components of the front-end system 1603 and/or power-management system 1605.

The front-end system 1603 aids in conditioning signals transmitted to and/or received from the antennas 1604. In the illustrated embodiment, the front-end system 1603 includes one or more bias control circuits 1610 for controlling power-amplifier biasing, one or more power amplifiers 1611, one or more low-noise amplifiers (LNAs) 1612, one or more filters 1613, one or more switches 1614, and one or more duplexers 1615. However, other implementations are possible.

For example, the front-end system 1603 can provide a number of functionalities, including amplifying signals for transmission, amplifying received signals, filtering signals, switching between different bands, switching between different power modes, switching between transmission and receiving modes, duplexing of signals, multiplexing of signals (for instance, diplexing or triplexing), or some combination thereof.

In certain implementations, the mobile device 1600 supports carrier aggregation, thereby providing flexibility to increase peak data rates. Carrier aggregation can be used for both Frequency Division Duplexing (FDD) and Time Division Duplexing (TDD), and may be used to aggregate a plurality of carriers or channels. Carrier aggregation includes contiguous aggregation, in which contiguous carriers within the same operating frequency band are aggregated. Carrier aggregation can also be non-contiguous, and can include carriers separated in frequency within a common band or in different bands.

The antennas 1604 can include antennas used for a wide variety of types of communications. For example, the antennas 1604 can include antennas for transmitting and/or receiving signals associated with a wide variety of frequencies and communications standards.

In certain implementations, the antennas 1604 support multiple-input and multiple-output (MIMO) communications and/or switched diversity communications. For example, MIMO communications use multiple antennas for communicating multiple data streams over a single radio frequency channel. MIMO communications benefit from higher signal-to-noise ratio, improved coding, and/or reduced signal interference due to spatial multiplexing differences of the radio environment. Switched diversity refers to communications in which a particular antenna is selected for operation at a particular time. For example, a switch can be used to select a particular antenna from a group of antennas based on a variety of factors, such as an observed bit error rate and/or a signal-strength indicator.

The mobile device 1600 can operate with beamforming in certain implementations. For example, the front-end system 1603 can include phase shifters having variable phase controlled by the transceiver 1602. Additionally, the phase shifters are controlled to provide beam formation and directivity for transmission and/or reception of signals using the antennas 1604. For example, in the context of signal transmission, the phases of the transmit signals provided to the antennas 1604 are controlled such that radiated signals from the antennas 1604 combine using constructive and destructive interference to generate an aggregate transmit signal exhibiting beam-like qualities with more signal strength propagating in a given direction. In the context of signal reception, the phases are controlled such that more signal energy is received when the signal is arriving to the antennas 1604 from a particular direction. In certain implementations, the antennas 1604 include one or more arrays of antenna elements to enhance beamforming.

The baseband system 1601 is coupled to the user interface 1607 to facilitate processing of various user input and output (I/O), such as voice and data. The baseband system 1601 provides the transceiver 1602 with digital representations of transmit signals, which the transceiver 1602 processes to generate RF signals for transmission. The baseband system 1601 also processes digital representations of received signals provided by the transceiver 1602. As shown in FIG. 16, the baseband system 1601 is coupled to the memory 1606 to facilitate operation of the mobile device 1600.

The memory 1606 can be used for a wide variety of purposes, such as storing data and/or instructions to facilitate the operation of the mobile device 1600 and/or to provide storage of user information.

The power-management system 1605 provides a number of power-management functions of the mobile device 1600. In certain implementations, the power-management system 1605 includes a power amplifier (PA) supply control circuit that controls the supply voltages of the power amplifiers 1611. For example, the power-management system 1605 can be configured to change the supply voltage(s) provided to one or more of the power amplifiers 1611 to improve efficiency, such as power added efficiency (PAE). One or more of the power amplifiers 1611 may be implemented as Doherty power amplifiers in accordance with one or more embodiments described herein and having one or more advantageous features described herein.

The power-management system 1605 can operate in a selectable supply control mode, such an average power tracking (APT) mode or an envelope tracking (ET) mode. In the illustrated embodiment, the selected supply control mode of the power management system 1605 is controlled by the transceiver 1602. In certain implementations, the transceiver 1602 controls the selected supply control mode using the serial interface 1609.

As shown in FIG. 16, the power-management system 1605 receives a battery voltage from the battery 1608. The battery 1608 can be any suitable battery for use in the mobile device 1600, including, for example, a lithium-ion battery. Although the power-management system 1605 is illustrated as separate from the front-end system 1603, in certain implementations all or part (for instance, a PA supply control circuit) of the power-management system 1605 is integrated into the front end system 1603.

In some implementations, a device and/or a circuit having one or more features described herein can be included in an RF device such as a wireless device. Such a device and/or a circuit can be implemented directly in the wireless device, in a modular form as described herein, or in some combination thereof. In some examples, such a wireless device can include, for example, a cellular phone, a smart phone, a hand-held wireless device with or without phone functionality, a wireless tablet, etc.

Table 1 below details of the ruggedness for a full radio-frequency module implementing the class E design amplifier and inverse F amplifier. Ruggedness is usually used to test the capability of a power amplifier (PA) withstanding extreme conditions including load mismatch, extreme temperatures, input power and supply voltages. A failure in ruggedness will cause permanent damage to the PA and malfunction of a module or device in which the PA is implemented. Ruggedness under code temperature (−30 C) is the worst case for the PA.

The ruggedness testing conditions include a 40 MHz resource block (RB), −30 C, and a 6:1 voltage standing wave ratio (VSWR) at a fixed output power output. Parts are tested under a Vcc that is increased by 100 mV per test cycle until damages are observed and parts are recorded as a failure.

TABLE 1

| Part # | Failing Vcc | Passing Vcc |
|---|---|---|
| Class E Part #1 | 4.5 V | 4.4 V |
| Class E Part #2 | 4.5 V | 4.4 V |
| Class inv. F Part #1 | 5.8 V | 5.7 V |
| Class inv. F Part #2 | 5.8 V | 5.7 V |

As can be seen from Table 1, the class inverse F part#1 and #2 can tolerate a biasing Vcc of 5.7 V and fail at 5.8 V while the Class E part #1 and #2 can only survive under 4.4 V and fail or break at 4.5 V which demonstrates that the inverse F design is far more rugged.

While various values of improved performance have been stated, these are only example values.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above description using the singular or plural number may also include the plural or singular number respectively. The word “or” in reference to a list of two or more items, that word covers all of the following interpretations of the word: any of the items in the list, all of the items in the list, and any combination of the items in the list.

Having described above several aspects of at least one example, various alterations, modifications, and improvements will readily occur to those skilled in the art. Such alterations, modifications, and improvements are intended to be part of this disclosure and are intended to be within the scope of the invention. Accordingly, the foregoing description and drawings are by way of example only, and the scope of the invention should be determined from proper construction of the appended claims, and their equivalents.

The teachings of the invention provided herein can be applied to other systems, not necessarily the system described above. The elements and acts of the various examples described above can be combined to provide further examples.

While some examples of the inventions have been described, these examples have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

What is claimed is:

1. A Doherty power amplifier comprising:
an input configured to receive an input signal to be amplified and to split the input signal into a first portion and a second portion, the input signal having an operating frequency;
a carrier amplifier path coupled to the input to receive the first portion, the carrier amplifier path including a carrier amplifier coupled to a differential inverter, the carrier amplifier being configured to amplify the first portion and provide an amplified first portion to the differential inverter, the differential inverter having a capacitance configured to make the differential inverter behave as a short circuit at odd harmonics of the operating frequency, the capacitance coupling a first path and a second path of the differential inverter in parallel; and
a peaking amplifier path coupled to the input to receive the second portion and comprising a peaking amplifier configured to amplify the second portion.

2. The Doherty power amplifier according to claim 1 wherein the capacitance is configured to make the differential inverter behave as an open circuit at the second harmonic of the operating frequency and as a short circuit at the third harmonic of the operating frequency.

3. The Doherty power amplifier according to claim 1 wherein the carrier amplifier is a class inverse F amplifier.

4. The Doherty power amplifier according to claim 1 wherein the carrier amplifier and the peaking amplifier are configured to operate as push-pull amplifiers.

5. The A Doherty power amplifier according to claim 4 wherein the first path and the second path correspond to the push path and the pull path of the carrier amplifier respectively.

6. The Doherty power amplifier according to claim 1 wherein the capacitance is configured to provide a phase shift to the amplified first portion.

7. The Doherty power amplifier according to claim 6 wherein the phase shift is a 90 degree phase shift.

8. The Doherty power amplifier according to claim 1 wherein the first path and the second path each include an inductance, and the differential inverter further includes a second capacitance coupling the first path and the second path in parallel and being located after each of the inductances of the first path and the second path.

9. The Doherty power amplifier according to claim 1 wherein the differential inverter is configured to output an inverted amplified first portion and the Doherty power amplifier further comprises a balanced to unbalanced matching circuit.

10. The Doherty power amplifier according to claim 1 wherein the carrier amplifier path comprises a carrier amplifier path output configured to output an inverted amplified first portion and the peaking amplifier path comprises a peaking amplifier output configured to output an amplified second portion.

11. The Doherty power amplifier according to claim 10 further comprising a combiner coupled to the carrier amplifier path output and the peaking amplifier path output and being configured to combine the inverted amplified first portion and the amplified second portion to yield an amplified radio-frequency signal.

12. A method of amplifying a radio-frequency signal, the method comprising:
receiving a radio-frequency signal at an input of a Doherty power amplifier, the radio-frequency signal having an operating frequency;
splitting the input signal into a first portion and a second portion;
providing the first portion to a carrier amplifier path and the second portion to a peaking amplifier path;
amplifying the first portion at a carrier amplifier on the carrier amplifier path and providing an amplified first portion to a differential inverter on the carrier amplifier path, the differential inverter having a capacitance making the differential inverter behave as a short circuit at odd harmonics of the operating frequency, the capacitance coupling a first path and a second path of the differential inverter in parallel; and
amplifying the second portion at a peaking amplifier on the peaking amplifier path to provide an amplified second portion.

13. The method of amplifying the radio-frequency signal according to claim 12 wherein the capacitance makes the differential inverter behave as an open circuit at the second harmonic of the operating frequency and as a short circuit at the third harmonic of the operating frequency.

14. The method of amplifying the radio-frequency signal according to claim 12 wherein the carrier amplifier is a class inverse F amplifier.

15. The method of amplifying the radio-frequency signal according to claim 12 wherein the carrier amplifier and the peaking amplifier operate as push-pull amplifiers.

16. The method of amplifying the radio-frequency signal according to claim 12 wherein the capacitance provides a phase shift to the amplified first portion.

17. The method of amplifying the radio-frequency signal according to claim 12 wherein the first path and the second path each include an inductance, and the differential inverter further includes a second capacitance coupling the first path and the second path in parallel and being located after each of the inductances of the first path and the second path.

18. The method of amplifying the radio-frequency signal according to claim 12 wherein the carrier amplifier path comprises a carrier amplifier path output for outputting an inverted amplified first portion and the peaking amplifier path comprises a peaking amplifier output for outputting an amplified second portion.

19. A power amplifier module comprising:
a packaging substrate configured to receive a plurality of components; and
a Doherty power amplifier implemented on the packaging substrate, the Doherty power amplifier comprising
an input configured to receive an input signal to be amplified and to split the input signal into a first portion and a second portion, the input signal having an operating frequency,
a carrier amplifier path coupled to the input to receive the first portion, the carrier amplifier path including a carrier amplifier coupled to a differential inverter, the carrier amplifier being configured to amplify the first portion and provide an amplified first portion to the differential inverter, the differential inverter having a capacitance configured to make the differential inverter behave as a short circuit at odd harmonics of the operating frequency, the capacitance coupling a first path and a second path of the differential inverter in parallel, and
a peaking amplifier path coupled to the input to receive the second portion and comprising a peaking amplifier configured to amplify the second portion.

20. The power amplifier module according to claim 19 wherein the packaging substrate comprises a semiconductor die, the capacitance being implemented on-die.
